(19) United States
(12) Patent Application Publication
(10) Pub. No.: US 2013/0228211 A1
(43) Pub. Date: Sep. 5, 2013

(54) PHOTOVOLTAIC ELEMENT WITH OPTICALLY FUNCTIONAL CONVERSION LAYER FOR IMPROVING A CONVERSION OF INCIDENT LIGHT AND PRODUCTION METHOD FOR THE ELEMENT

(71) Applicants: Jochen Fritsche, Zoerbig (DE); Michael Bauer, Leipzig (DE)

(72) Inventors: Jochen Fritsche, Zoerbig (DE); Michael Bauer, Leipzig (DE)

(21) Appl. No.: 13/600,679

(22) Filed: Aug. 31, 2012

Related U.S. Application Data
(63) Continuation of application No. PCT/EP2011/001133, filed on Mar. 8, 2011.

(30) Foreign Application Priority Data
Mar. 8, 2010 (DE) 10 2010 015 848.8

(51) Int. Cl. H01L 31/0232; H01L 31/0203

(52) U.S. Cl. CPC H01L 31/02322; H01L 31/0203
USPC 136/249; 136/257; 438/65

(57) ABSTRACT

The invention relates to a photovoltaic element including an optically functional surface layer for improving a conversion of the incident light. The functioning of the layer involves absorbing incident sunlight having a low wavelength and emitting it again as light radiation having a higher wavelength, so that this light spectrum becomes usable for solar cells. In order to solve the currently unsolved problem of embedding such a layer into a thin-film solar cell with a substrate arranged on the front side, while ensuring high weathering resistance, it is proposed to arrange the optical functional layer in an additional encapsulation element on the front side and thus to construct the photovoltaic element as a double- or multiple composite assembly.

### RELATED APPLICATIONS

This application is a continuation of International Application PCT/EP2011/001133 filed Mar. 8, 2011 claiming priority from German Patent Application DE 10 2010 015 848.8 filed on Mar. 8, 2010, both of which are incorporated in their entirety by this reference.

### FIELD OF THE INVENTION

The invention relates to a photovoltaic element including a solar cell and an encapsulation element for protecting the solar cell against weather influences according to the preamble of claim 1 and to a method for producing the photovoltaic element.

### BACKGROUND OF THE INVENTION

A solar cell produces electrical energy in that it absorbs energy of incident sunlight and thus generates an electrode movement which can be captured as electrical current. Thus, however, not the entire spectrum of sunlight is available to the solar cell for generating energy. The sunlight covers a wavelength range of approximately 200 nm up to far beyond 2000 nm, wherein the highest radiation intensity is in a range of approximately 300 to 1000 nm.

A solar cell for example based on cadmium-telluride has its optimum absorption spectrum in a wavelength range of approximately 400 to 900 nm. Highly energetic low wavelength sunlight in a range of 200 to 400 nm therefore cannot be converted.

This problem, however, can be partially compensated by so-called “luminescence downshifting” methods, abbreviated LDS. Thus, optically functional pigments are used which change the frequency of the light permeating the pigments. For example, incident light below the absorption wavelength range is absorbed and put out again in a higher wavelength range in the optimum absorption spectrum of the solar cell. Applying the pigments to a solar cell embedded in a suitable carrier material, for example a gel, an emulsion or a foil, could thus increase the energy absorption of the solar cell and thus increase its efficiency.

Due to technical problems, this method is still not used in standard applications. The materials presently used do not have the required weather resistance to maintain its optical properties over the product warranty period of more than 25 years for solar modules. A simple application to the sun side of the solar cell is therefore not possible. WO 2008/110567 A1 therefore proposes to apply the optical material for wavelength shifting in a suitable carrier material as a conversion layer to the front side of the solar cell that is oriented towards the incident light and to then cover the conversion layer with the encapsulation element in the form of a cover glass. This is possible for example for crystalline silicon solar cells or for substrate arrangements of thin film solar cells since the encapsulation element configured as a cover glass for protecting the solar cells against weather influences is applied as a final step in the production method and not exposed to any damaging conditions of the manufacturing process of the solar cells any more.

This method, however, is not applicable for all solar modules in thin film configuration. The method is not applicable for thin film modules with so-called superstrate configuration in which the thin films with the photoactive layer are initially applied to the front side glass and are only subsequently connected with the backside encapsulation. If the optical material for the LDS method were initially applied to the bottom side of the front side glass, the thermal and chemical influences of the manufacturing process for the solar thin film cells would destroy the pigments. For a subsequent application on the module surface long term stability is not provided as recited supra.

Therefore there is no solution for using the LDS technology for superstrate thin film modules.

### BRIEF SUMMARY OF THE INVENTION

Therefore, it is an object of the invention to make the LDS method usable also for superstrate thin film solar modules and to assure functionality over the duration of the product warranty. This object is achieved with a photovoltaic element for converting incident light into electrical power, comprising: a thin film solar cell with a transparent substrate which is arranged on a front side of the thin film solar cell which front side is oriented towards incident light, wherein an encapsulation element is arranged on the transparent substrate of the thin film solar cell for protecting the thin film solar cell against environmental impacts, wherein the encapsulation element includes a transparent glass- or plastic material plate or -foil, wherein the encapsulation element includes a conversion layer with an optically functional material which absorbs the incident light of a particular wavelength range and emits light of a different wavelength range, wherein the encapsulation element is provided as an interconnection of a plurality of layers, wherein the encapsulation element includes an interconnection forming intermediary layer which establishes an interconnection between the encapsulation element and the substrate of the thin film solar cell, wherein the optically functional material is arranged in the intermediary layer and/or in the glass- or plastic material plate or -foil.

The object is also achieved by a method for producing a photovoltaic element for converting incident light into electrical power, including a thin film solar cell with a transparent substrate that is arranged on a front side of the thin film solar cell which front side is oriented the towards incident light, wherein an encapsulation element is provided which includes a transparent glass- or plastic material plate or -foil, wherein the encapsulation element includes a conversion layer with an optically functional material which absorbs incident light of a particular wavelength range and reemits the light as a light of a different wavelength range, wherein the encapsulation element is arranged on the substrate of the thin film solar cell for protecting the thin film solar cell against environmental impacts, wherein the glass- or plastic material plate or -foil is arranged on the substrate after producing the thin film solar cell, wherein an interconnection forming intermediary layer is arranged between the glass- or plastic material plate or -foil, and wherein the optically functional material is arranged in the intermediary layer and/or in the glass- or plastic plate or -foil. Advantageous embodiments of the invention are provided in the dependent claims.

According to the invention, it is provided for the photovoltaic element in superstrate configuration that an encapsulation element is arranged on the front side which includes the conversion layer. The conversion layer includes optically functional particles which absorb incident light of a particular wavelength range and emit the light again as light radiation in a different wavelength range. Thus, the optically functional particles are embedded in the encapsulation element which protects them against environmental impacts and is additionally used as a carrier medium for the particles. Thus another encapsulation element is arranged on the substrate of the thin film solar cell already provided, wherein the encapsulation element already includes the conversion layer. This solution comes as a surprise to a person skilled in the art because so far the substrate of the thin film solar cell was always used as outer front encapsulation of a photovoltaic element in superstrate configuration and another additional encapsulation was not considered for economical reasons and for reasons of optical efficiency.

Since this encapsulation element includes a glass or plastic plate or foil, this configuration besides the additional weather protection of the photovoltaic element as a double interconnection between the substrate of the thin film solar cell and the glass or plastic plate or foil has the advantage of increased mechanical stability, for example during transport or assembly. This yields simplified assembly because the photovoltaic element is less damage prone due to increased stability.

On the other hand side, the thickness of the substrate and/or of the glass or plastic plate or foil and optionally of the backside encapsulation element can be reduced in a controlled manner through the double interconnection with identical stability compared to photovoltaic elements without this additional encapsulation element on the front side. This yields overall a reduction in the material thicknesses used which yields overall a thinner and lighter photovoltaic element. Thus, the thicknesses of the particular layers can be adapted in an optimum manner to the particular application and the preconditions of production. Furthermore, the optical properties of the particular layers through which the sunlight impacts the solar cell, can be optimized one by one in order to thus reduce the overall losses through absorption and reflection.

Through the front configuration according to the invention as a double interconnection, a particularly advantageous effect is achieved which was not achievable so far because using such front side double interconnection was not considered for optical reasons because of the additional boundary surfaces. Furthermore, any additional materials increase the cost and the weight of the photovoltaic element. Surprisingly, it has become apparent that the configuration with multiple interconnections through integration of the conversion layer provides better properties for the photovoltaic element with respect to optical efficiency and also with respect to stability and mass than currently available photovoltaic elements with superstrate configuration.

Preferably, the encapsulation element is configured as an interconnection of a plurality of layers. However, the encapsulation element can also be configured as a single layer, for example as a plastic plate or foil which is directly applied to the substrate, for example through melting or similar.

In a advantageous embodiment, the encapsulation element includes an interconnection forming intermediary layer which provides an interconnection between the encapsulation element and the substrate of the thin film solar cell.

Particularly advantageously the conversion layer is arranged between the substrate of the thin film solar cell and the glass- or plastic-plate or foil. Alternatively or additionally it can also be provided that the conversion layer is configured as glass- or plastic plate or foil in that the optically functional material is arranged in the glass- or plastic layer.

The conversion layer is provided as an emulsion, a gel, a paste, a lacquer a glue or a foil.

In a particular embodiment, the photovoltaic element includes a plurality of thin film solar cells which are uniformly configured and arranged on the substrate in the substrate arrangement as monolithically wired thin layer packets. These can be for example solar cells made from amorphous silicon, cadmium-sulfite or cadmium-telluride.

Preferably the encapsulation element is configured so that it has at least one of the following properties: self-cleaning (lotus effect), reflection reduction or increase scratch resistance.

In a particularly advantageous embodiment, the photovoltaic element according to the invention includes the encapsulation element directly on the front of the substrate which encapsulation element includes the following layers: a first interconnection forming intermediary layer which is directly arranged on the substrate and a first transparent glass- or plastic plate or foil arranged on the first connection forming intermediary layer. Thus, the photovoltaic element is particularly compact and also configured stable and can furthermore be produced in a particularly simple manner.

Particularly advantageously, another encapsulation element is provided directly on a backside of the thin film solar cell, wherein the encapsulation element includes the following layers: a second interconnection forming intermediary layer which is arranged on the thin film solar cell and a second transparent glass or plastic plate or foil that is arranged on the second interconnection forming intermediary layer. Thus, the photovoltaic element is encapsulated in a weather resistant manner on all sides, wherein preferably also an outer frame or an outer gluing is added which connects the two encapsulation elements or reaches around the two encapsulation elements.

Independent patent protection is claimed for a method for producing a photovoltaic element in superstrate configuration for converting incident light into power including a thin film solar cell with a transparent substrate which is arranged on the front side of the thin film solar cell that is oriented towards the incident light, wherein the method is characterized in that an encapsulation element is arranged on the substrate of the thin film cell for protecting the solar cell against environmental impacts, wherein the encapsulation element includes a transparent glass- or plastic plate or -foil, wherein the encapsulation element includes a conversion layer (2) with an optically functional material which absorbs incident light of a particular wavelength range and reemits the light as light radiation in a changed wavelength range. This method is characterized in that it is particularly simple and can be easily integrated into existing processes.

It is provided in a particularly advantageous manner that after producing the thin film solar cell, the glass or plastic plate or foil is arranged on the substrate, wherein an interconnection forming intermediary layer is arranged between the glass or plastic plate or foil, wherein the optically functional material is arranged in the intermediary layer and/or in the glass- or plastic layer. This provides that the formation of the thin film solar cell is completed before the frontal encapsulation layer is applied. This provides that no additional process step has to be integrated into existing processing lines since the production of the thin film solar cell is not changed but only an additional encapsulation step is added. Thus, scrap is kept at a minimum because there is no other production step for the thin film solar cell which would be the case when a conversion layer is directly applied to the front of the thin film solar cell through coating.

A foil is advantageously used as an intermediary layer. The foil can be advantageously configured as EVA (ethylene-vinyl-acetate), PVB (poly-vinyl-butyral), PE (polyethylene)-foil.

Alternatively it can also be provided that the intermediary layer is applied as a lacquer, gel, emulsion, glue or paste onto the glass or plastic plate before the glass or plastic plate or the foil is arranged on the substrate.

### BRIEF DESCRIPTION OF THE DRAWINGS

Certainly a foil and also a glue or similar can be provided as well as two intermediary layers. Preferably, however, only one intermediary layer is used. Further advantages and features of the invention are described with reference to embodiments based on the drawing figures, wherein:

FIG. 1 illustrates a schematic not to scale cross-section through the structure of a thin film solar module; and

FIG. 2 illustrates a diagram including:
an intensity of incident sunlight in various wavelength ranges,
an absorption spectrum of a solar cell illustrated with reference to an embodiment of a cadmium-telluride solar cell, and possible absorption- and emission ranges of the conversion layer.

### DETAILED DESCRIPTION OF THE INVENTION

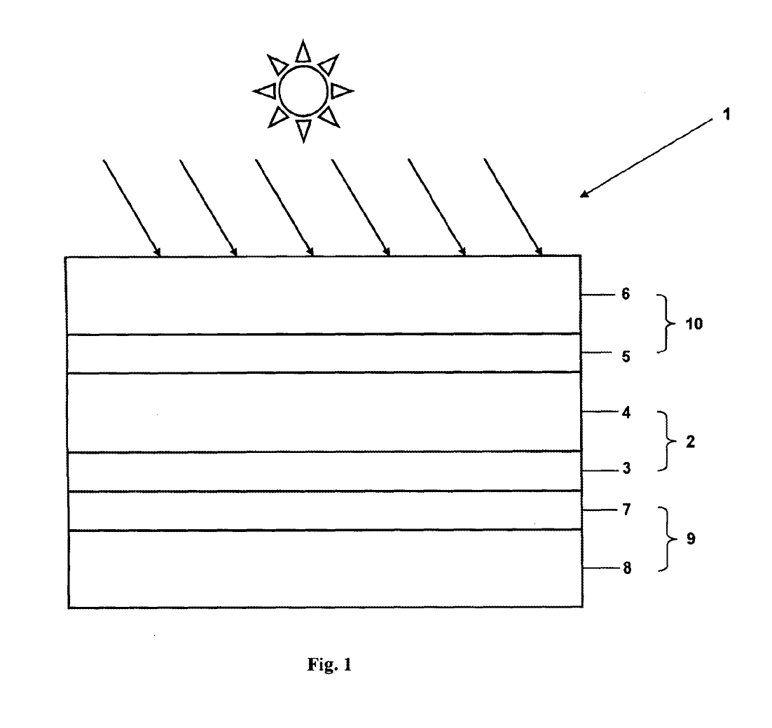

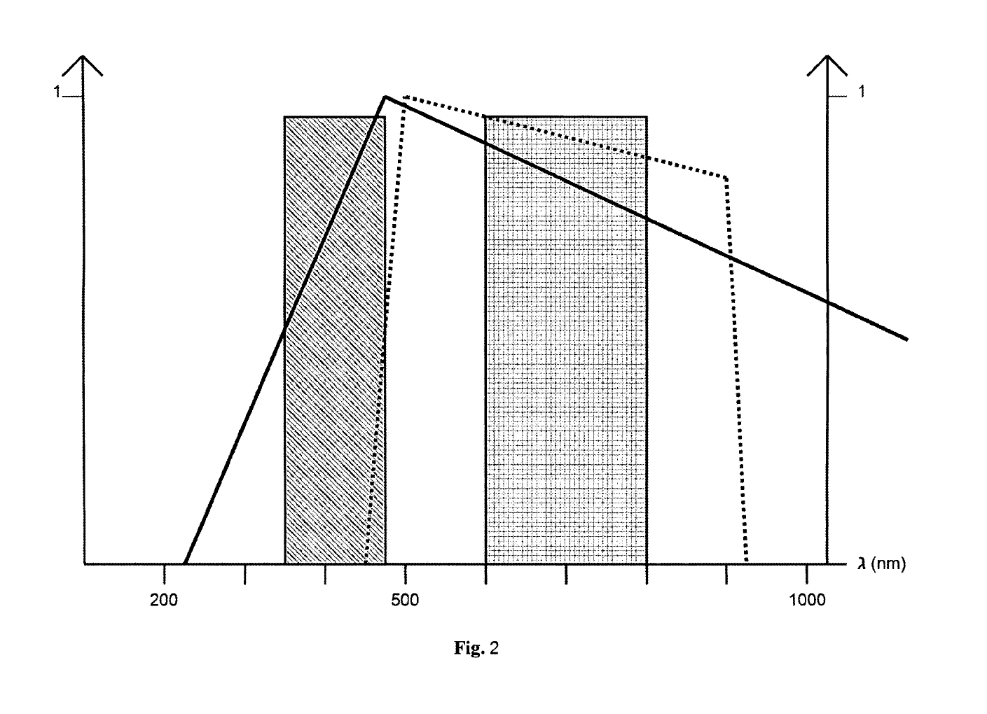

FIG. 1 illustrates a schematic cross-section of a thin film solar module 1 which includes a thin film solar cell 2 with a thin film packet 3 and a substrate 4. On the front side of the thin film cell 2, a conversion layer 5 and thereon a first protective layer is arranged which is configured for example as first glass- or plastic plate or foil 6. The conversion layer 5 is thus configured as first interconnection generating intermediary layer, namely for example as a transparent glue foil, in particular EVA, PVB or PE foil in which the optically functional material is embedded. On the backside of the thin film solar cell 2, a second interconnection forming intermediary layer 7 is arranged that is typically also configured as transparent glue foil or a second protection layer which is configured as second glass or plastic plate or foil 8, wherein the layer thicknesses are not illustrated to scale. Above the layer structure, the incident solar radiation is schematically illustrated through parallel arrows.

The second glass- or plastic plate or -foil 8 of the solar module typically has a thickness of 2 mm to 3 mm. Also the substrate 4 and the first glass- or plastic plate or -foil 6 have a thickness of approximately 2 mm to 3 mm. This particular configuration yields a three-pane interconnection which has particularly high stability. Alternatively as described supra, also particular thicknesses can be reduced while maintaining the typical overall stability.

The thin film packet 3 of the thin film solar cell 2 includes a positively doted semiconductor layer and a negatively doted semiconductor layer and electrical contacts on the front side and on the backside, wherein the electrical contact on the side oriented towards the light is made from transparent metal oxides, the negative semiconductor layer is made from cadmium sulfite and the positive semiconductor layer is made from cadmium telluride and the electrical contact on the backside is made from a metal material. Thus, overall, the entire thin film packet 3 is only a couple of micrometers thick, so that it is combined into one layer in the figure.

Thus, it is evident that the photovoltaic element 1 according to the invention does not only include a backside encapsulation element 9 which is formed from the second interconnection forming intermediary layer 7 and the second glass- or plastic plate or -foil 8, but also a front side encapsulation element 10 which is formed from the first interconnection forming intermediary layer 7 and the first glass- or plastic plate or -foil 8. This front side encapsulation element 10 is configured in the illustrated embodiment as an interconnection of plural layers 5, 6. The first intermediary layer 5 includes optically functional particles which are embedded in a suitable carrier medium; presently the particles are included in the foil. Thus, the carrier medium is also used as weather protection for the optically functional particles. Additional weather protection for the conversion layer 5 is provided through the first glass- or plastic plate or -foil 6.

Alternatively or additionally, it can also be provided that the first glass- or plastic material plate or -foil includes the optically functional material.

The production method according to the invention is particularly simple and cost-effective because the first glass- or plastic plate or -foil 6 is simply connected with the substrate 4 for this purpose. Thus, either an interconnection forming intermediary layer in the form of a glue is arranged in between or the entire packet is laminated, preferably simultaneously with a lamination of the frontal encapsulation element 9. Alternatively or additionally also the first glass- or plastic material plate or foil 6 can be provided with a paste, a lacquer or similar and is subsequently arranged on the substrate 4 and laminated.

Eventually also a single layer configuration of the frontal encapsulation element 10 can be provided where no interconnection forming intermediary layer 5 is provided, but the substrate 4 and the glass- or plastic material plate or -foil 6 are directly connected with one another. Then the conversion layer would form a unit with the first glass- or plastic material plate or -foil, wherein optically functional material is accordingly received in the first glass- or plastic plate or -foil.

FIG. 2 illustrates the utility that can be derived from the LDS method for a solar cell. Thus, the wavelength range of the incident sunlight (solid line) and also the absorption range of a solar cell based on cadmium telluride (dotted line) are drawn in a diagram. The wavelength of the incident light is thus plotted over the x-axis. A y-axis is drawn at the left and also at the right edge of the diagram, wherein the left y-axis indicates a relative intensity of the sunlight with a maximum of 1, the right y-axis on the other hand side indicates the relative absorption of the solar cell, also with the maximum of 1. Thus, however it is appreciated that the axes designate the same relative intensities but different absolute intensities. Thus, there is no wavelength range in which the solar cell can absorb more light than emitted by the sun.

It is apparent that the radiation of the sunlight spectrum starts at wavelengths of slightly above 200 nm. Then there is a sharp increase up to a maximum at approximately 500 nm, subsequently the intensity is continuously reduced. At a wavelength of 1000 nm, the wavelength has decreased to approximately 50% of its maximum. Radiation with longer wavelengths is not relevant for the invention and therefore not drawn.

The cadmium telluride solar cell, however, is capable of using light starting at a wavelength of approximately 450 nm for energy production. Thereafter, there is a quick increase of the absorption capability up to a maximum of 500 nm, thereafter the absorption capability decreases continuously. At slightly above 900 nm, there is an instant drop. Light with higher wavelengths cannot be used in practical applications.

Additionally, the diagram illustrated in FIG. 2 includes flat blocks which illustrate the possible absorption range (hatched block) and also the possible emission range (checkered block) of a conversion layer including optically functional material for light wave downshifting. Thus, these blocks do not represent the entire spectrum of the conversion layer but only represent possible ranges.

Thus it is apparent that the absorption spectrum is in a range of approximately 350 to 475 nm, thus in the high energy wavelength range of the sunlight which, however, cannot be absorbed by the solar cell. The emission spectrum in turn is in a range of 600 to 800 nm and therefore in the range of a high absorption of the solar cell.

### REFERENCE NUMERALS AND DESIGNATIONS

1 photovoltaic element
2 thin film solar cell
3 thin film packet
4 substrate
5 first interconnection forming intermediary layer/conversion layer
6 first glass- or plastic material plate or -foil
7 second interconnection forming intermediary layer
8 second glass- or plastic material plate or -foil
9 rear encapsulation element
10 front encapsulation element

What is claimed is:

1. A photovoltaic element for converting incident light into electrical power, comprising:
a thin film solar cell with a transparent substrate which is arranged on a front side of the thin film solar cell which front side is oriented towards incident light,
wherein an encapsulation element is arranged on the transparent substrate of the thin film solar cell for protecting the thin film solar cell against environmental impacts,
wherein the encapsulation element includes a transparent glass- or plastic material plate or -foil,
wherein the encapsulation element includes a conversion layer with an optically functional material which absorbs the incident light of a particular wavelength range and emits light of a different wavelength range,
wherein the encapsulation element is provided as an interconnection of a plurality of layers,
wherein the encapsulation element includes an interconnection forming intermediary layer which establishes an interconnection between the encapsulation element and the substrate of the thin film solar cell,
wherein the optically functional material is arranged in the intermediary layer or in the glass- or plastic material plate or -foil.

2. The photovoltaic element according to claim 1, wherein the intermediary layer is provided as the conversion layer.

3. The photovoltaic element according to claim 1,
wherein the conversion layer is arranged between the substrate of the thin film solar cell and the glass- or plastic material plate or -foil, or
wherein the conversion layer is provided as the glass- or plastic material plate or -foil, and
wherein the optically functional material is arranged in the glass- or plastic material layer or -foil.

4. The photovoltaic element according to claim 1, wherein the conversion layer is provided as an emulsion, a gel, a paste, a lacquer, a glue or a foil.

5. The photovoltaic element according to claim 1, wherein the photovoltaic element includes a plurality of thin film solar cells which are configured and arranged in a superstrate configuration as monolithically electrically connected thin film packets in a uniform manner on the substrate.

6. The photovoltaic element according to claim 1, wherein the encapsulation element is provided so that it has at least one of the following properties: reflection reduction, scratch resistance and self-cleaning.

7. The photovoltaic element according to claim 1,
wherein the photovoltaic element includes the encapsulation element directly on the front side on the substrate, and
wherein the encapsulation element includes the following layers:
a first interconnection forming intermediary layer which is directly arranged on the substrate, and
a first transparent glass- or plastic material plate or -foil arranged on the first interconnection forming intermediary layer.

8. The photovoltaic element according to claim 1,
wherein the photovoltaic element includes a second encapsulation element directly on a backside on the thin film solar cell, and
wherein the second encapsulation element includes the following layers:
a second interconnection forming intermediary layer which is arranged on the thin film solar cell, and
a second transparent glass- or plastic material plate or -foil arranged on the second interconnection forming intermediary layer.

9. A method for producing a photovoltaic element for converting incident light into electrical power, including a thin film solar cell with a transparent substrate that is arranged on a front side of the thin film solar cell which front side is oriented towards the incident light,
wherein an encapsulation element is provided which includes a transparent glass- or plastic material plate or -foil,
wherein the encapsulation element includes a conversion layer with an optically functional material which absorbs incident light of a particular wavelength range and reemits the light as a light of a different wavelength range,
wherein the encapsulation element is arranged on the substrate of the thin film solar cell for protecting the thin film solar cell against environmental impacts,
wherein the glass- or plastic material plate or -foil is arranged on the substrate after producing the thin film solar cell,
wherein an interconnection forming intermediary layer is arranged between the glass- or plastic material plate or -foil, and
wherein the optically functional material is arranged in the intermediary layer or in the glass- or plastic plate or -foil.

10. The method according to claim 9, wherein a foil is used as the intermediary layer.

11. The method according to claim 9, wherein the intermediary layer is applied to the glass- or plastic material plate or -foil as a lacquer, gel, emulsion, glue or paste before the glass- or plastic material plate or -foil is arranged on the substrate.

12. The method according to claim 9, wherein the method is used to produce a photovoltaic element according to one of the claims 1 through 8.

13. A photovoltaic element for converting incident light into electrical power, comprising:
a thin film solar cell with a transparent substrate which is arranged on a front side of the thin film solar cell which front side is oriented towards incident light,
wherein an encapsulation element is arranged on the transparent substrate of the thin film solar cell for protecting the thin film solar cell against environmental impacts,
wherein the encapsulation element includes a transparent glass- or plastic material plate or -foil,
wherein the encapsulation element includes a conversion layer with an optically functional material which absorbs the incident light of a particular wavelength range and emits light of a different wavelength range,
wherein the encapsulation element is provided as an interconnection of a plurality of layers,
wherein the encapsulation element includes an interconnection forming intermediary layer which establishes an interconnection between the encapsulation element and the substrate of the thin film solar cell,
wherein the optically functional material is arranged in the intermediary layer and in the glass- or plastic material plate or -foil.

14. The photovoltaic element according to claim 1,
wherein the conversion layer is arranged between the substrate of the thin film solar cell and the glass- or plastic material plate or -foil, and
wherein the conversion layer is provided as the glass- or plastic material plate or -foil, and
wherein the optically functional material is arranged in the glass- or plastic material layer or -foil.

15. A method for producing a photovoltaic element for converting incident light into electrical power, including a thin film solar cell with a transparent substrate that is arranged on a front side of the thin film solar cell which front side is oriented towards the incident light,
wherein an encapsulation element is provided which includes a transparent glass- or plastic material plate or -foil,
wherein the encapsulation element includes a conversion layer with an optically functional material which absorbs incident light of a particular wavelength range and reemits the light as a light of a different wavelength range,
wherein the encapsulation element is arranged on the substrate of the thin film solar cell for protecting the thin film solar cell against environmental impacts,
wherein the glass- or plastic material plate or -foil is arranged on the substrate after producing the thin film solar cell,
wherein an interconnection forming intermediary layer is arranged between the glass- or plastic material plate or -foil, and
wherein the optically functional material is arranged in the intermediary layer and in the glass- or plastic plate or -foil.
